(19) United States
(12) Patent Application Publication
(10) Pub. No.: US 2025/0101964 A1
(43) Pub. Date: Mar. 27, 2025

(54) MOTION ELEMENT

(71) Applicant: NIPPON TELEGRAPH AND TELEPHONE CORPORATION, Tokyo (JP)

(72) Inventors: Riku TAKAHASHI, Musashino-shi, Tokyo (JP); Aya TANAKA, Musashino-shi, Tokyo (JP); Masumi YAMAGUCHI, Musashino-shi, Tokyo (JP)

(73) Assignee: NIPPON TELEGRAPH AND TELEPHONE CORPORATION, Tokyo (JP)

(21) Appl. No.: 18/721,581

(22) PCT Filed: Dec. 22, 2021
(86) PCT No.: PCT/JP2021/047496

§ 371 Date: Jun. 18, 2024

(51) Int. Cl. F03G 7/06

(52) U.S. Cl. CPC F03G 7/06

(57) ABSTRACT

Provided is a motion element including: a substrate; a gel layer made of a stimulus-responsive gel and provided on one surface of the substrate; and an input unit that inputs a stimulus to which the stimulus-responsive gel reacts in a non-contact manner at an arbitrary position on the gel layer, in which adhesive regions where the substrate and the gel layer adhere to each other and a non-adhesive region where the substrate and the gel layer do not adhere to each other are formed at an interface between the substrate and the gel layer, the adhesive regions are provided on both sides of the non-adhesive region in a plan view, and the input unit inputs the stimulus to the gel layer overlapping the non-adhesive region.

### TECHNICAL FIELD

The present invention relates to a motion element.

### BACKGROUND ART

In recent years, soft motion elements (soft actuators) that enable smooth motion and supple motion have been actively studied. Since such a motion element can particularly move in a manner imitating a living body, motion elements are expected to be applied in a wide range of fields such as the welfare field such as in artificial limbs, the medical and health field such as an artificial organ, and an engineering field such as an industrial robot.

Among them, motion elements using a hydrogel as a material have been widely studied. A hydrogel is a substance that contains a polymer having a three-dimensional network structure and swells with a solvent contained in most of the volume. A representative of the solvent contained in a hydrogel is water. It is known that a hydrogel exhibits properties such as a low coefficient of friction, high flexibility, and being capable of permeating a substance through a solvent contained therein. The hydrogel has a characteristic that the volume changes depending on the solvent content. A motion element using a hydrogel as a material performs motion control using the characteristics of the hydrogel.

For example, a device that operates using a volume change of a hydrogel in response to a stimulus such as heat, electricity, light, a magnetic field, pH, or a chemical substance is known (see, for example, Non Patent Literature 1).

### CITATION LIST

### Non Patent Literature

Non Patent Literature 1: M. Wei, et al. Polym. Chem., 8, 127 (2017).

### SUMMARY OF INVENTION

### Technical Problem

However, in the device described in Non Patent Literature 1, it is difficult to control the volume change of the hydrogel at an arbitrary position, and the behavior of the device is limited to simple deformation. In addition, in the device described in Non Patent Literature 1, the operation of the device depends only on the amount of change in volume of the hydrogel. Therefore, in the device described in Non Patent Literature 1, only a small and low-speed operation can be performed.

The present invention has been made in view of such circumstances, and an object of the present invention is to provide a motion element capable of performing complex motion control and capable of operating at a higher speed than in the related art.

### Solution to Problem

In order to solve the above problems, one aspect of the present invention provides a motion element including: a substrate; a gel layer made of a stimulus-responsive gel and provided on one surface of the substrate; and an input unit configured to input a stimulus to which the stimulus-responsive gel reacts in a non-contact manner at an arbitrary position on the gel layer, in which adhesive regions where the substrate and the gel layer adhere to each other and a non-adhesive region where the substrate and the gel layer do not adhere to each other are formed at an interface between the substrate and the gel layer, the adhesive regions are provided on both sides of the non-adhesive region in a plan view, and the input unit inputs the stimulus to the gel layer overlapping the non-adhesive region.

### Advantageous Effects of Invention

According to the present invention, it is possible to provide a motion element capable of performing complex motion control and capable of operating at a higher speed than in the related art.

### BRIEF DESCRIPTION OF DRAWINGS

FIG. 1 is a schematic perspective view of a motion element 100.

FIG. 2 is a cross-sectional view taken along line II-II in FIG. 1 as viewed in a direction of arrows.

FIG. 3 is a cross-sectional view taken along line III-III in FIG. 1 as viewed in a direction of arrows.

FIG. 4 is a set of schematic cross-sectional views illustrating a modification example of the motion element.

FIG. 5 is a set of enlarged photographs of a layered body produced in Examples.

FIG. 6 is a set of enlarged photographs showing a state of change of a layered body irradiated with near-infrared light.

FIG. 7 is a set of enlarged photographs showing a state of change of a layered body irradiated with scanning near-infrared light.

### DESCRIPTION OF EMBODIMENTS

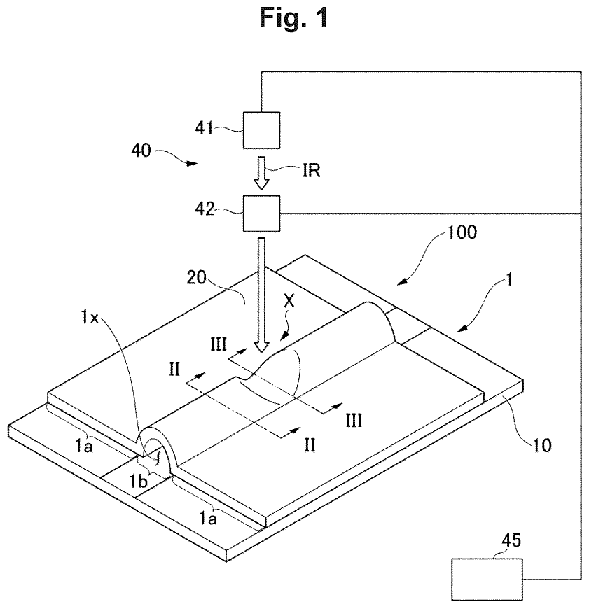

A motion element according to a first embodiment will be described below with reference to FIGS. 1 to 4. In all of the following drawings, dimensions, ratios, and the like of each component are appropriately changed in order to make the drawings easily viewable.

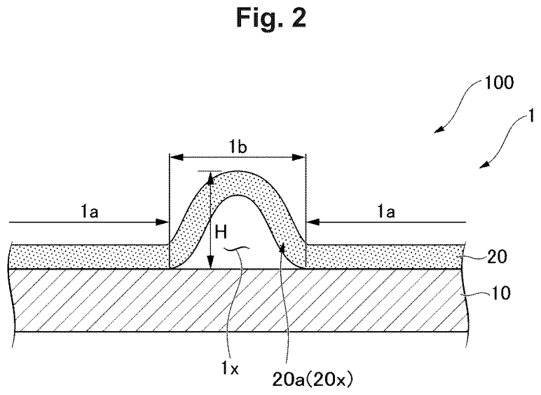

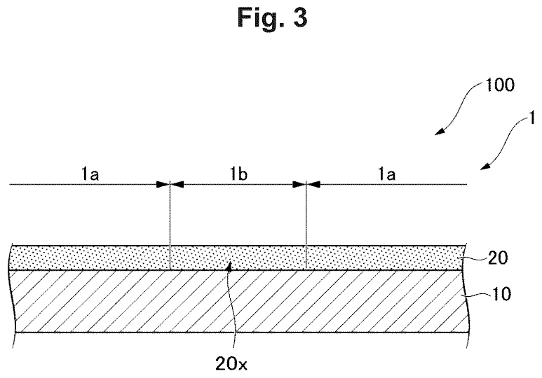

FIG. 1 is a schematic perspective view of a motion element 100. FIG. 2 is a cross-sectional view taken along line II-II in FIG. 1 as viewed in a direction of arrows. FIG. 3 is a cross-sectional view taken along line III-III in FIG. 1 as viewed in a direction of arrows.

As illustrated in FIG. 1, the motion element 100 includes a substrate 10, a gel layer 20, and an input unit 40 that inputs a stimulus to the gel layer 20. In the following description, the substrate 10 and the gel layer 20 may be collectively referred to as a layered body 1.

### (Substrate)

The substrate 10 supports the gel layer 20. A rigidity modulus of the substrate 10 is different from a rigidity modulus of the gel layer 20. For example, the rigidity modulus of the substrate 10 is higher than the rigidity modulus of the gel layer 20.

As a material for forming the substrate 10, various materials can be selected regardless of whether being an organic material or an inorganic material as long as the effect of the invention is not impaired. The substrate 10 may or may not have optical transparency.

Examples of the organic material as the material for forming the substrate 10 include a polymer material and an elastomer. Examples of the polymer material include thermoplastic resins such as polyvinyl chloride, polystyrene, ABS resin, and polylactic acid, and thermosetting resins such as polyimide and phenol resin.

Examples of the elastomer include polysilicone and synthetic rubber. The substrate 10 formed of an elastomer as the forming material is easily deformed according to stress. In the layered body 1 having such a substrate 10, the gel layer 20 can be deformed with the deformation of the substrate 10.

As the material for forming the substrate 10, a gel having a degree of swelling different from that of a stimulus-responsive gel as a material for forming the gel layer 20 to be described later can also be used.

The above-described organic material may contain various additives, and various functions based on physical properties of the additives may be added to the substrate 10. For example, the substrate 10 may contain carbon nanotubes, gold nanostructures, porphyrin derivatives, polydopamine, indocyanine green, or the like in the organic material, and generate heat by receiving light.

Examples of the inorganic material as the material for forming the substrate 10 include glass excellent in transparency and chemical stability, a conductor that generates heat when energized, a magnetic metal body that generates heat when stimulated by a magnetic field, a piezoelectric element that generates power by stress, and a light emitting element that emits light when energized. Examples of the light emitting element include a light emitting diode.

Various types of processing may be applied to at least one of surface and inside of the substrate 10 by a known microfabrication technique. For example, the substrate 10 may have irregularities or grooves in the surface.

### (Gel Layer)

The gel layer 20 is a layer provided on one surface of the substrate 10 using a stimulus-responsive gel as a forming material. The stimulus-responsive gel contains a polymer and a solvent that swells the polymer as a forming material.

Here, the “stimulus-responsive gel” refers to a gel having a property of changing a retention amount (degree of swelling) of a solvent retained by the gel in response to stimuli such as heat, light, electricity, and pH. Simply bringing the solvent into contact with the polymer constituting the gel or removing the solvent from the gel by drying is not included in “stimulation”. The stimulus-responsive gel may be one in which the three-dimensional network structure of the polymer is changed by the stimulus that changes the molecular structure of the polymer constituting the gel, and the degree of swelling is changed. In addition, the stimulus-responsive gel may be one in which a substance contained in the gel generates heat by giving a stimulus to the substance, and a solvent retained by the gel is discharged (evaporated) to the outside of the gel by the generated heat.

Here, the “degree of swelling” is represented by the ratio (V/V₀) of the volume (V) of the entire gel (polymer network+solvent after change) when the solvent content changes to the volume (original volume V₀) of the polymer network+solvent at the time of preparing the gel. Usually, the degree of swelling is strongly affected by the molecular structure (type, amount, position, three-dimensional structure, and crosslinking density of functional group) of the polymer. In the stimulus-responsive gel, the amount of solvent that can be retained by the polymer changes depending on the input stimulus.

Examples of the stimulus-responsive gel include a stimulus-responsive hydrogel capable of swelling with an aqueous solvent and a stimulus-responsive organogel (stimulus-responsive elastomer) capable of swelling with a lipophilic solvent.

### (Stimulus-Responsive Hydrogel)

As the polymer contained in the stimulus-responsive hydrogel, a polymer whose molecular structure changes (responds) by various stimuli as follows can be used.

Examples of the polymer that responds to heat include a lower critical solution temperature (LCST) type polymer and an upper critical solution temperature (UCST) type polymer.

Examples of the LCST type polymer include poly(N-isopropylacrylamide) and poly(methyl vinyl ether). In a case where the gel layer 20 contains the LCST type polymer, when the swollen gel layer 20 is heated, the solvent releases and shrinks.

Examples of the UCST type polymer include poly(allylamine-co-allylurea). In a case where the gel layer 20 contains the UCST type polymer, when the gel layer 20 is heated, the solvent is absorbed from the surroundings and swells.

Examples of the polymer material that responds to pH include a polymer electrolyte obtained by polymerizing anionic monomers or cationic monomers. In a case where the gel layer 20 contains a polymer that responds to pH, a change in pH changes the charge state of the functional group, and as a result, a change in osmotic pressure inside the gel is induced, and the gel layer swells by absorbing the solvent from the surroundings to cancel the change.

For example, when the gel layer 20 supports a water-soluble photo acid generator (diphenyl-2,4,6-trimethylphenylsulfonium p-toluenesulfonate) or a photo base generator (1,2-diisopropyl-3-[bis(dimethylamino)methylene]guanidinium=2-(3-benzoylphenyl)propionate), a pH change can be locally induced by light irradiation.

Examples of the polymer that responds to light include polymers having spiropyran or azobenzene in the skeleton. A molecular structure having an inclusion complex of azobenzene and cyclodextrin as a crosslinking point may be introduced into the polymer that responds to light. In the polymer having such a molecular structure, the crosslinking point is changed by light stimulation, and the degree of swelling can be changed.

As the polymer to which a biomolecule responds, a polymer incorporating DNA or protein as a crosslinking point may be used. In a case where the gel layer 20 contains a polymer to which a biomolecule responds, crosslinking by DNA or protein is denatured (broken) or formed by thermal denaturation, pH change, or the like, whereby the crosslinking density of the gel changes, and swelling (deswelling) associated with an osmotic pressure change is induced.

In addition, as a magnetic field-responsive gel, a temperature-responsive polymer gel in which magnetic particles (such as iron) are combined may be used. In the magnetic field-responsive gel, magnetic particles placed in a magnetic field generate heat by magnetic induction heating, and the degree of swelling of the temperature-responsive polymer in response to the heat changes, thereby causing a volume change.

Also, as a microwave-responsive gel, a temperature-responsive polymer gel in which a microwave absorbing material (polyaniline or the like) is combined may be used. In the microwave-responsive gel, the microwave absorbing material generates heat by microwave irradiation, and the degree of swelling of the temperature-responsive polymer in response to the heat changes, thereby causing a volume change.

In addition, as the hydrogel whose degree of swelling changes by drying or dehydration with an organic solvent, synthetic water-soluble polymers such as polyacrylamide and polyvinyl alcohol which are simple water-swelling gels, polysaccharides such as chitosan, alginic acid, and cellulose, and polymers obtained by crosslinking proteins such as collagen and albumin can be used.

In addition, a plurality of the above-described polymers may be mixed to form a hydrogel that responds to multiple stimuli.

These polymers have a three-dimensional network structure and swell by containing an aqueous solvent in most of the volume. Examples of the aqueous solvent include water, or a co-solvent of water as a main component and a liquid miscible with water (ionic liquid, dimethylsulfoxide, dimethylformamide, methanol, ethanol, acetone, and the like).

In order to modulate the physical strength, the stimulus-responsive hydrogel may form an interpenetrating network structure. Specifically, after forming a gel containing a polymer having a first network structure, the gel is swollen in an aqueous solution containing components (monomers, crosslinking agents, or initiators) forming a second network structure. Thereafter, by polymerizing components forming the second network structure, the second network is formed in an interpenetrating manner with the first network structure to form an interpenetrating network structure. By forming such a structure, the mechanical strength can be enhanced.

A method for synthesizing the polymer contained in the hydrogel is not particularly limited. In the case of an acrylic polymer, chemical crosslinking by a polymerization reaction of an acrylic group can be mentioned. In the case of polysaccharides and proteins, gelation by physical bonding may be used, or a chemical crosslinking agent represented by glutaraldehyde may be used.

The type of a polymerization reaction in polymerizing the acrylic monomer is not particularly limited, and an example thereof includes radical polymerization using a water-soluble photopolymerization initiator. Examples of the water-soluble photoinitiator include 2-oxoglutaric acid, 4′-(2-hydroxyethoxy)-2-hydroxy-2-methylpropiophenone (Irgacure 2959), lithium phenyl(2,4,6-trimethylbenzoyl) phosphinate (LAP), and 2,2′-azobis[2-methyl-N-(2-hydroxyethyl) propionamide](VA-086).

As the polymerization reaction, radical polymerization using a thermal polymerization initiator can also be employed. Examples of the thermal polymerization initiator include ammonium peroxodisulfate (APS) and potassium peroxodisulfate (KPS). It may also be combined with N,N,N′,N′-tetramethylethane-1,2-diamine (TEMED) which is a polymerization accelerator.

At the time of radical polymerization, a deoxidizing agent may be added to a reaction system in order to prevent polymerization inhibition by oxygen. Examples of the deoxidizing agent include a combination of glucose and glucose oxidase. Further, the radical polymerization may be performed under an inert gas atmosphere such as nitrogen or argon.

### (Stimulus-Responsive Organogel)

The stimulus-responsive organogel contains a polymer (elastomer) and a photothermal conversion material that generates heat by receiving light as a forming material.

Examples of the polymer (elastomer) contained in the stimulus-responsive organogel include silicone such as polydimethylsiloxane, synthetic rubbers such as butadiene rubber, chloroprene rubber, isoprene rubber, acrylic rubber, and urethane rubber, thermoplastic resins such as natural rubber, polyethylene, polyvinyl chloride, polypropylene, polystyrene, polymethyl methacrylate, and polyethylene terephthalate, and thermosetting resins such as phenol-based and epoxy-based thermosetting resins. These resins can induce a volume change by a change in solvent content due to drying or the like.

Examples of the photothermal conversion material include metal nanoparticles, a carbon material, and a conductive polymer. In the stimulus-responsive organogel, the photothermal conversion material is dispersed in a size capable of receiving irradiated light.

Examples of the solvent contained in the stimulus-responsive organogel include various organic solvents capable of swelling various elastomers. Examples thereof include methanol, ethanol, acetone, dimethyl sulfoxide, dimethylformamide, ethyl acetate, chloroform, tetrahydrofuran, benzene, toluene, xylene, pyridine, carbon disulfide, ethylene glycol, and glycerol.

### (Other Materials)

Various additives can be added to the stimulus-responsive gel as long as gel formation is not inhibited. Examples of the additive include a biomolecule for improving bioaffinity, a silver nanoparticle or a surfactant for exhibiting antibacterial properties, an ionic liquid or a conductive polymer for increasing conductivity, and a magnetic nanoparticle for reacting with a magnetic field. By adding these additives to the hydrogel, an arbitrary function can be imparted to the hydrogel.

In addition, a thermal conversion material may be added as an additive. As the thermal conversion material, a material that generates heat by receiving light (photothermal conversion material) can be used, and the gel layer 20 can generate heat by irradiating the gel layer 20 with light. Examples of the thermal conversion material include graphene, graphene oxide, metal nanoparticles, and polydopamine.

For example, as a polymer contained in the stimulus-responsive gel, a polymer that changes a molecular structure by thermal stimulation and a photothermal conversion material that generates heat in response to light are combined to swell a solvent, whereby a heat-stimulus-responsive gel that responds to light can be obtained.

The shape of the gel layer 20 is not particularly limited, and various shapes can be selected according to a use form. The gel layer 20 can employ, for example, a film shape, a plate shape, or a block shape. Among these shapes, in a case where it is desired to induce hollow shape deformation, a film shape is more preferable from the viewpoint of enabling large deformation with a small force.

The thickness of the gel layer 20 is not particularly limited, but is preferably a thickness that can maintain structural strength to the extent that it is not crushed by its own weight. For example, in a case where poly(N-isopropylacrylamide) which is an LCST type polymer is used as the material of the gel layer 20, the thickness is preferably 10 to 1000 μm. In addition, since quick response is possible and structural strength can be maintained, the thickness of the gel layer 20 is more preferably 60 to 600 μm.

The mechanical properties of the gel layer 20 can be improved by performing one or more of (1) chemically crosslinking the polymer constituting the gel, (2) physically crosslinking the polymer constituting the gel, and (3) increasing the concentration of the polymer contained in the gel.

### (Layered Body)

In the layered body 1, an adhesive region 1a where the substrate 10 and the gel layer 20 adhere to each other and a non-adhesive region 1b where the substrate 10 and the gel layer 20 do not adhere to each other are formed at an interface between the substrate 10 and the gel layer 20.

In the layered body 1 illustrated in FIG. 1, the non-adhesive region 1b is provided in a band shape on one surface of the substrate 10. The adhesive regions of the layered body 1 are provided on both sides in the extending direction of the non-adhesive region 1b in a plan view (in a field of view along the normal of the substrate 10). Note that the pattern of the adhesive region 1a and the non-adhesive region 1b illustrated in FIG. 1 is an example, and various pattern shapes according to design can be employed.

### (Input Unit)

The input unit 40 inputs a stimulus to which the stimulus-responsive gel constituting the gel layer 20 reacts to an arbitrary position on the gel layer 20 in a non-contact manner. The input unit 40 includes a stimulation unit 41, an adjustment unit 42, and a control unit 45.

The stimulation unit 41 applies, to the gel layer 20, a stimulus to which the stimulus-responsive gel constituting the gel layer 20 reacts. Examples of the type of stimulation include light, magnetic fields, microwaves, and sound waves. The stimulation unit 41 has a configuration capable of applying each stimulus. For example, in a case where the stimulation unit 41 applies light as a stimulus, the stimulation unit 41 uses a light source that emits the light.

The adjustment unit 42 arbitrarily adjusts the position of the stimulus that the stimulation unit 41 applies to the gel layer 20. The adjustment unit 42 may adjust the position of the stimulus by moving the stimulation unit 41, or may directly control the stimulus emitted from the stimulation unit 41 to adjust the position of the stimulus.

As the adjustment unit 42, a known configuration having the above function can be employed. For example, in a case where the stimulation unit 41 applies light as a stimulus, the adjustment unit 42 may be a servomotor that changes the position of the light source that is the stimulation unit 41, or may be an optical system such as a galvanometer mirror that controls the emission direction of the light emitted from the light source.

The control unit 45 controls operations of the stimulation unit 41 and the adjustment unit 42.

The input unit 40 illustrated in FIG. 1 irradiates an arbitrary position X of the gel layer 20 with an infrared ray IR emitted from the stimulation unit 41 which is a laser light source using the adjustment unit 42 which is a galvanometer mirror.

The motion element 100 having the above configuration is driven as follows. In the following description, it is assumed that the gel layer 20 is a heat-stimulus-responsive hydrogel, and the heat-stimulus-responsive hydrogel contains an LCST type polymer.

First, as described above, in the motion element 100, the gel layer 20 is not fixed to the substrate 10 in the non-adhesive region 1b, but is fixed to the substrate 10 in the adhesive region 1a. In FIGS. 2 and 3, a portion of the gel layer 20 that planarly overlaps the non-adhesive region 1b is indicated by reference numeral 20x (gel layer 20x).

When such a motion element 100 is immersed in, for example, a solvent contained in the stimulus-responsive gel forming the gel layer 20, the gel layer 20 swells and isotropically increases in volume. At this time, the gel layer 20x can freely extend in an extending direction of the non-adhesive region 1b and a direction away from the substrate 10 when the volume is increased by swelling.

On the other hand, the gel layer 20 is fixed to the substrate 10 in the adhesive regions 1a located on both sides of the non-adhesive region 1b. Therefore, when the volume of the gel layer 20x increases due to swelling, the gel layer is restricted from extending in a direction intersecting the extending direction of the non-adhesive region 1b, and the internal pressure increases as the volume increases.

As a result, as illustrated in FIG. 2, the gel layer 20x buckles and greatly swells in a direction away from the substrate 10 in order to alleviate the increase in the internal pressure due to the volume increase. Accordingly, a tubular portion 20a having a pipeline 1x surrounded by the gel layer 20x and the substrate 10 is formed in the motion element 100.

The shape of the pipeline 1x can be controlled by controlling the pattern shapes of the adhesive region 1a and the non-adhesive region 1b.

The shape of the pipeline 1x can be controlled by adjusting the type of the gel layer 20, the ratio between the rigidity modulus of the substrate 10 and the rigidity modulus of the gel layer 20, the thickness of the gel layer 20, and the like. The rigidity modulus of the gel layer 20 and the swelling rate of the gel layer 20 can be controlled by changing the type of the polymer monomer constituting the gel layer 20, the type and amount of the crosslinking agent to be used, and the like.

On the other hand, the tubular portion 20a (gel layer 20x) is heated by the input unit 40 at the position X irradiated with the infrared ray IR as a thermal stimulus. By heating, in the gel layer 20x, the LCST type polymer which is a thermostimulable polymer and water are phase-separated, and the gel layer 20x shrinks. As a result, as illustrated in FIG. 3, at the position X irradiated with the infrared ray IR, the pipeline 1x is closed, and the gel layer 20x functions as a shutoff valve of the tubular portion 20a.

The change in shape as described above is caused by a difference between the swelling rate of the gel layer 20 to which no thermal stimulation is applied and the swelling rate of the gel layer 20 to which thermal stimulation is applied at the position X. The change of the gel layer 20 before and after applying the thermal stimulation is reversible. That is, when the thermal stimulation at the position X is stopped, in the motion element 100 immersed in the solvent, the gel layer 20 absorbs the surrounding solvent and swells again, and the tubular portion 20a is also formed at the position X. As a result, at the position X, the pipeline 1x opens again as illustrated in FIG. 2.

Thus, the deformation of the gel layer 20x is caused by two factors of (i) an increase in volume of the entire gel layer 20 due to swelling of the stimulus-responsive gel, and (ii) buckling of the gel layer 20x in which elongation is restricted. Therefore, for example, as compared with the case where the gel layer 20 overlapping the adhesive region 1a is deformed only by the factor (i), in the gel layer 20x, the deformation amount (difference in height H of the gel layer 20x between before and after the stimulus response) becomes large.

In addition, in a case where an attempt is made to achieve a deformation amount similar to that of the gel layer 20x only by the factor (i), it is necessary to increase the thickness of the gel layer 20 itself and to increase the difference between before and after swelling of the gel layer. However, in this case, as the thickness of the gel layer increases, the swelling time of the solvent with respect to the gel layer also increases. On the other hand, since the gel layer 20x is deformed by two factors (i) and (ii), large deformation can be performed while the swelling time with respect to the gel layer 20x is short. As a result, desired deformation (for example, opening and closing of the pipeline 1x) can be performed at high speed.

As described above, in the motion element 100, the swelling rate of the gel layer 20 is controlled by the stimulus locally input to the gel layer 20, and the opening and closing of the tubular portion 20a (pipeline 1x) can be controlled.

The layered body 1 included in the motion element 100 can be manufactured by the following method. A case where the polymer contained in the stimulus-responsive gel is an acrylic polymer will be described as an example.

### (Method 1)

First, the surface of the substrate 10 is surface-treated with a known silane coupling agent having a functional group polymerizable with an acrylic monomer.

Examples of the functional group of the silane coupling agent include a (meth)acrylic group. In this case, 3-(methacryloyloxy)propyltrimethoxysilane, for example, can be used as the silane coupling agent.

The surface of the substrate 10 is washed with an aqueous solution of sodium hydroxide, treated with oxygen plasma or a piranha solution, and then applied with a silane coupling agent, whereby the surface of the substrate 10 can be surface-treated with the silane coupling agent. The piranha solution is a common name that refers to a mixed solution of concentrated sulfuric acid and a hydrogen peroxide solution.

Next, a mask of a photoresist is formed on the surface of the substrate treated with the silane coupling agent using a known photolithography technique, and mask plasma treatment is performed with a pattern of the non-adhesive region 1b, thereby removing the silane coupling agent at a position corresponding to the non-adhesive region 1b. Thereby, a pattern of the region where the silane coupling agent is formed is formed.

Next, the acrylic monomer is radically polymerized on the surface of the substrate 10, and the obtained polymer is immersed in a solvent to obtain the gel layer 20 of the stimulus-responsive gel in which the acrylic polymer is swollen with the solvent. Thereby, the layered body 1 having the gel layer 20 is obtained. The layered body 1 has an adhesive region 1a and a non-adhesive region 1b according to the pattern of the silane coupling agent.

### (Method 2)

In a case where the material of the substrate 10 is an elastomer or a polymer film that swells with an organic solvent, first, an initiator solution in which a hydrogen abstraction type photoinitiator is dissolved in an organic solvent is adjusted, and the initiator solution is applied to the substrate 10 to swell the initiator solution over the entire substrate 10.

Examples of the organic solvent include ethanol and acetone. Examples of the hydrogen abstraction type photoinitiator include benzophenone, Michler's ketone, and Michler's ethyl ketone.

Next, the substrate 10 containing the initiator solution is subjected to pattern exposure, and the photoinitiator contained in the substrate 10 is consumed in a predetermined pattern.

Next, the acrylic monomer is radically polymerized on the surface of the substrate 10 containing the initiator solution using a photopolymerization initiator. By irradiating the monomer with light, the photopolymerization initiator reacts to obtain an acrylic polymer.

At this time, in the substrate 10, a hydrogen abstraction type photoinitiator reacts with light irradiation to extract hydrogen atoms from the polymer constituting the substrate 10. Accordingly, a reaction point (radical) of radical polymerization is generated in the polymer constituting the substrate 10. At the time of radical polymerization of the acrylic monomer, a reaction point generated in the substrate 10 reacts with a radical of the acrylic monomer or a radical of the acrylic polymer (oligomer) generated by the radical polymerization, and the acrylic polymer is introduced into the substrate 10.

Since the photoinitiator contained in the substrate 10 is consumed according to the pattern of the pattern exposure, the acrylic polymer is not introduced into the substrate 10 at the portion subjected to the pattern exposure, and the acrylic polymer is introduced into the substrate 10 at the portion not subjected to the pattern exposure.

By immersing the obtained acrylic polymer in a solvent, the gel layer 20 made of a stimulus-responsive gel in which the acrylic polymer is swollen with the solvent is obtained. Thereby, the layered body 1 having the gel layer 20 is obtained. The layered body 1 has an adhesive region 1a and a non-adhesive region 1b according to pattern exposure.

### (Method 3)

In the above method 2, after the initiator solution is swollen over the entire substrate 10, pattern exposure is performed to consume the photoinitiator to form a pattern of the photoinitiator contained in the substrate 10, but other methods can also be employed.

First, a pattern of a water-repellent and oil-repellent functional group is formed on the surface of the substrate 10 in advance. The pattern of the water-repellent and oil-repellent functional group can be formed, for example, by surface-treating the substrate 10 with a silane coupling agent such as trichloro (1H,1H,2H,2H-heptadecafluorodecyl) silane and performing the above-described mask plasma treatment.

Next, the above-described initiator solution is applied to the surface of the substrate 10 on which the pattern of the water-repellent and oil-repellent functional group is formed. In the region where the pattern of the water-repellent and oil-repellent functional group is formed, the initiator solution is repelled, and swelling on the substrate 10 is suppressed. Thus, a pattern of the photoinitiator contained in the substrate 10 can be formed.

Hereinafter, the gel layer 20 made of a stimulus-responsive gel in which an acrylic polymer is swollen with a solvent is obtained in the same manner as in the above method 2. Thereby, the layered body 1 having the gel layer 20 is obtained.

Alternatively, the acrylic polymer may be polymerized in advance and then introduced onto the surface of the substrate 10.

### (Method 4)

First, the surface of the substrate 10 is surface-treated in a pattern shape with a known silane coupling agent having a reactive functional group (an amino group, an epoxy group, or the like) using the method described in the above method 1.

Next, the reactive functional group is bonded to a network invading polymer. Examples of the network invading polymer include chitosan, alginic acid, and polyvinyl alcohol.

Next, the stimulus-responsive gel is brought into contact with the substrate 10 on which the pattern of the network invading polymer is formed. The network invading polymer enters the inside of the network structure of the stimulus-responsive gel.

Next, the chemical structure is changed by a pH change, or the low molecular weight crosslinking agent is diffused and reacted, whereby the network invading polymer is crosslinked. Accordingly, the network invading polymer forms a network inside the network structure of the stimulus-responsive gel and is entangled with the stimulus-responsive gel, whereby a physical or chemical bond is formed between the stimulus-responsive gel and the network invading polymer. Thereby, the stimulus-responsive gel and the substrate 10 can be adhered to each other to obtain the layered body 1. The layered body 1 has an adhesive region 1a and a non-adhesive region 1b according to the pattern of the network invading polymer.

### (Method 5)

In addition, a cyanoacrylate-based adhesive may be applied to the surface of the substrate 10 in a predetermined pattern using a known method, and a sheet of stimulus-responsive gel molded into a predetermined shape may be brought into contact with the substrate. Thereby, the sheet of the stimulus-responsive gel and the substrate 10 can be adhered to each other to obtain the layered body 1. The layered body 1 has an adhesive region 1a and a non-adhesive region 1b according to the pattern of the adhesive.

According to the motion element having the above configuration, it is possible to perform complicated motion control and operate a higher speed than in the related art.

### MODIFICATION EXAMPLES

The motion element of the present invention is not limited to the above-described configuration. The motion element can have various functions according to the formation pattern of the non-adhesive region.

### Modification Example 1

For example, the input unit 40 may be capable of performing control to scan a stimulus (infrared ray IR) input to the gel layer 20. Accordingly, the motion element 100 can continuously move the position X to which the stimulus is input along the pipeline 1x. In such a motion element 100, the position where the pipeline 1x is closed continuously moves, and it can be used as a pump that pushes out the contents of the pipeline 1x in the scanning direction of the stimulus.

### Modification Example 2

In addition, in the motion element 100 of FIG. 1, the input unit 40 includes one stimulation unit 41, and the stimulation is input to one place (position X) of the gel layer 20, but the present invention is not limited thereto. The motion element may have a configuration in which the input unit 40 includes a plurality of stimulation units 41, and stimuli can be input to a plurality of locations at the same time.

In a case where the motion element having such a configuration includes the layered body 1 illustrated in FIG. 1, it is possible to open and close the pipeline 1x at a plurality of locations of the pipeline 1x by inputting stimuli to the plurality of locations of the pipeline 1x. Accordingly, the contents of the pipeline 1x can be shaken by the opening/closing operation, and the contents can be stirred.

### Modification Example 3

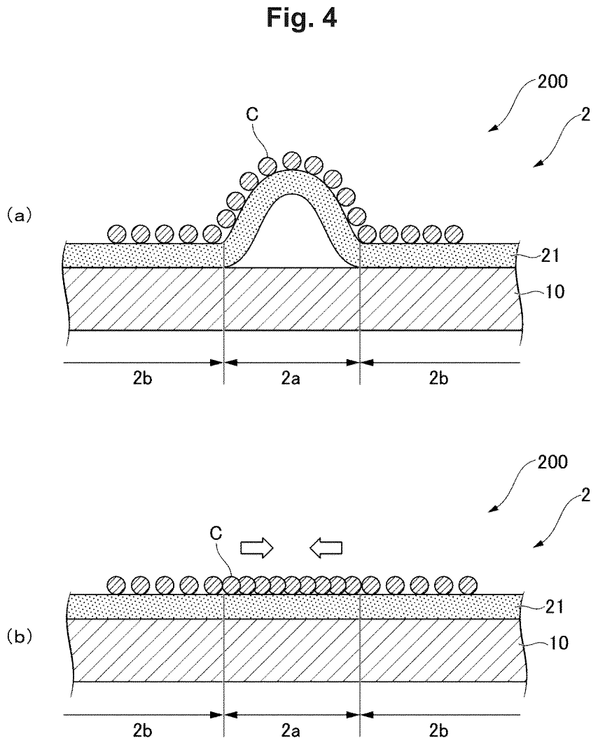

FIG. 4 is a set of schematic cross-sectional views illustrating a modification example of the motion element, and illustrates views corresponding to FIGS. 2 and 3. A motion element 200 in FIG. 4 includes a substrate 10, a gel layer 21 provided on the surface of the substrate 10, and an input unit (not illustrated) that inputs a stimulus to the gel layer 21. A combined configuration of the substrate 10 and the gel layer 21 is referred to as a layered body 2.

In the layered body 2, an adhesive region 2a where the substrate 10 and the gel layer 21 adhere to each other and a non-adhesive region 2b where the substrate 10 and the gel layer 21 do not adhere to each other are formed at an interface between the substrate 10 and the gel layer 21.

The gel layer 21 has at least a surface covered with a biocompatible material. The gel layer 21 may be a single layer made of a stimulus-responsive gel having biocompatibility as a whole, or may have a layered structure of a layer of a stimulus-responsive gel and a layer of a biocompatible material covering a surface of the layer.

In the case of the layered structure, a scaffold protein such as collagen or laminin can be used as the biocompatible material. As a layering method, a physical adsorption method of impregnating a substrate on which a gel layer is formed with a solution of a scaffold protein, a chemical immobilization method of immobilizing a surface of a layer of a stimulus-responsive gel formed in advance using a compound such as Sulfo-SANPAH (sulfosuccinimidyl 6-(4′-azido-2′-nitrophenylamino)hexanoate), or the like can be used.

When the gel layer 21 of such a motion element 200 is swollen, the gel layer 21 overlapping the non-adhesive region 2b is deformed as illustrated in FIG. 4(a), and is largely lifted from the substrate 10. In this state, when cells C are seeded on the surface of the gel layer 21 and cultured by being immersed in the medium, the cells C can be cultured on the surface of the gel layer 21.

At this time, when a stimulus to which the stimulus-responsive gel responds is input to a region of the gel layer 21 overlapping the non-adhesive region 2b, as illustrated in FIG. 4(b), the degree of swelling of the gel layer 21 overlapping the non-adhesive region 2b changes, and the gel layer shrinks until it becomes flat, for example. At this time, the surface area of the surface of the gel layer 21 overlapping the non-adhesive region 2b decreases as the volume changes. Accordingly, the plurality of cells C cultured on the surface of the gel layer 21 are reduced in distance in the direction intersecting the non-adhesive region 2b, and are pressed against each other.

Therefore, the motion element 200 can be used as a cell culture substrate capable of applying a mechanical stimulus to the cells C to be cultured. Such a motion element 200 is suitable for culturing myoblasts and vascular endothelial cells whose activity and secretion are changed by stretching stimulation.

The examples of the preferred embodiments according to the present invention have been described above with reference to the accompanying drawings, but the present invention is not limited to such examples. Various shapes, combinations, and the like of the constituent members shown in the above-described examples are merely examples, and various modifications can be made based on design, specifications, and the like without departing from the gist of the present invention.

### EXAMPLE

Hereinafter, the present invention will be described with reference to Examples, but the present invention is not limited to these Examples.

### «Manufacturing of Motion Element (Layered Body)»

First, a glass substrate as a substrate was washed with an aqueous sodium hydroxide solution and further treated with oxygen plasma. Thereafter, a silane coupling agent (3-(methacryloyloxy)propyltrimethoxysilane) having an adhesive functional group was applied to the plasma-treated surface of the glass substrate.

Next, a positive photoresist was spin-coated on the surface of the glass substrate coated with the silane coupling agent to form a resist layer. A resist layer having an opening portion with a width of 1 mm was formed by irradiating a strip shape having a line width of 1 mm with ultraviolet rays having a peak wavelength in an absorption wavelength band of the used positive photoresist through a mask and performing development.

Next, after oxygen plasma treatment was performed, the resist layer was removed with acetone to obtain a substrate on which a pattern of an adhesive functional group was formed. A region where the pattern of the adhesive functional group is formed corresponds to the adhesive region. In addition, the region overlapping the opening portion of the resist layer has the adhesive functional group removed by oxygen plasma treatment and corresponds to the non-adhesive region.

Next, a spacer having a thickness of 60 μm was disposed on the surface of the substrate on which the pattern of the adhesive functional group was formed, and then a monomer liquid was dropped onto the substrate. The monomer liquid was an aqueous dispersion containing N-isopropylacrylamide (2 mol/L) as a monomer, methylenebisacrylamide (0.02 mol/L) as a crosslinking agent, LAP (0.002 mol/L) as a photopolymerization initiator, and gold nanorods (0.1 mass % of the entire monomer liquid) as an additive.

Next, a cover glass (seal substrate) subjected to oxygen plasma treatment was placed to cover the monomer liquid, and the monomer liquid was sandwiched between the substrate and the seal substrate. The excess monomer liquid was wiped off, and then irradiated with ultraviolet rays (365 nm) to polymerize the monomer liquid.

After the monomer was polymerized, the seal substrate was removed and immersed in a large excess amount of pure water to remove unreacted gel precursor molecules, thereby obtaining a layered body included in the motion element of Example.

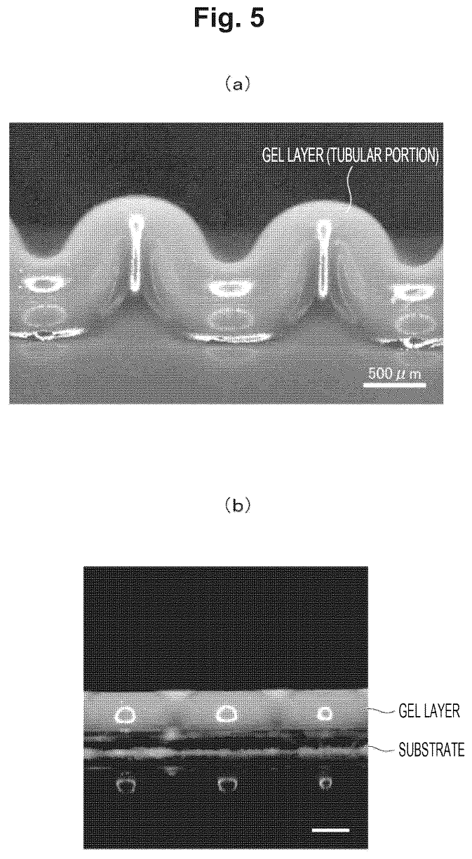

FIG. 5 is a set of enlarged photographs of a layered body produced by the above method, where FIG. 5(a) is a plan photograph and FIG. 5(b) is a side photograph. As illustrated in FIG. 5, the gel layer of the layered body is formed to be wavy and curved. The curved portion is located in a portion overlapping the non-adhesive region in the gel layer, and a pipeline is formed similarly to the tubular portion illustrated in FIG. 1.

Next, while the layered body thus produced was immersed in pure water, the layered body was irradiated with near-infrared light. A light source that emits near-infrared light and a control device that controls the light source correspond to an input unit of the present invention.

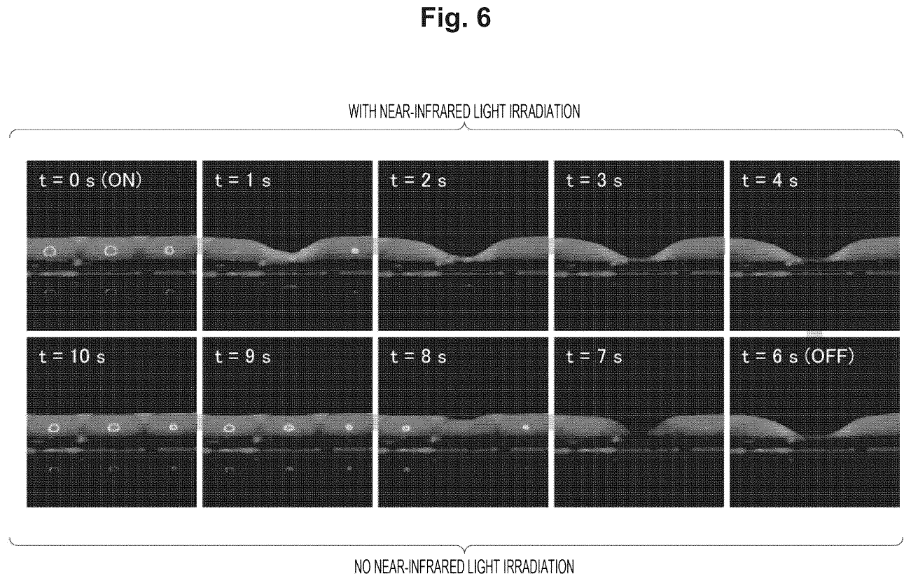

FIG. 6 is a set of enlarged photographs showing a state of change of the layered body irradiated with near-infrared light. The photographs illustrated in FIG. 6 are side photographs taken through a long wavelength cut filter.

As illustrated in FIG. 6, after 1 second (t=1 s) from the start of the irradiation of the near-infrared light (t=0 s (ON)), the deformation of the tubular portion started, and after 4 seconds (t=4 s), the pipeline was completely closed. In addition, swelling of the gel layer started immediately after the irradiation of near-infrared light was stopped (t=6 s (OFF)), and the pipeline was completely open without hysteresis after 4 seconds (t=10 s).

From these, in the produced motion element, it was confirmed that a part of the three-dimensional structure (tubular portion) can be changed by using light irradiation as a switch, and the light-irradiated portion functions as a dynamic valve that can be opened and closed.

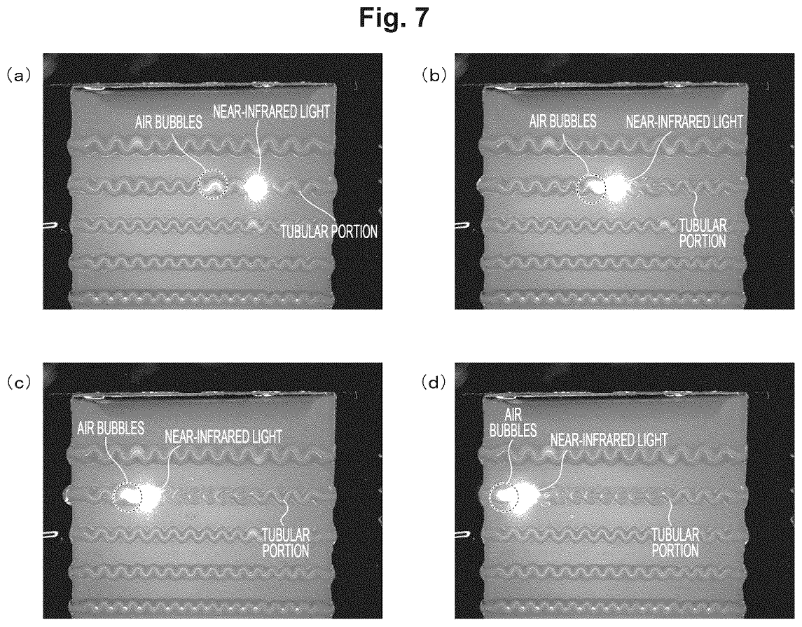

FIG. 7 is a set of enlarged photographs (plan photographs) showing a state of change of the layered body irradiated with scanning near-infrared light. In the photographs illustrated in FIG. 7, the tubular portion in the vicinity of air bubbles were irradiated with near-infrared rays in a state where the air bubbles were put in the pipeline. In FIG. 7, the positions of the air bubbles in the pipeline are indicated by arrows.

When the tubular portion of the layered body is irradiated with near-infrared light, the tubular portion shrinks as illustrated in FIG. 6, and a change occurs in which the pipeline is closed. As illustrated in FIGS. 7(a) to 7(d), it was confirmed that when the near-infrared light was scanned along the tubular portion, the air bubbles also moved with the scanning of the near-infrared light. Since the pipeline of the portion irradiated with the near-infrared light is closed and the closed portion of the pipeline is moved by scanning with the near-infrared light, it is considered that the air bubbles in the pipeline are also moved in a form of being pushed out to the closed portion of the pipeline.

From these, it was confirmed that in the produced motion element, liquids and solids contained in the flow path can be transported using light irradiation as a switch.

From the above, it was found that the present invention is useful.

The motion element according to the present invention is useful as an actuation device utilizing high-speed and large deformation of a three-dimensional shape, and is applicable to a wide range of fields such as fluidics, micropumps, cell culture, adhesion control, friction control, and wettability control.

### REFERENCE SIGNS LIST

1a, 2a, 3a, 4a, 5a Adhesive region
1b, 2b, 3b, 4b, 5b Non-adhesive region
1x Pipeline
10, 11, 12, 13 Substrate
20, 20x, 21 Gel layer
40 Input unit
100, 200, 300, 400, 500 Motion element
X Position

1. A motion element comprising:
a substrate;
a gel layer made of a stimulus-responsive gel and provided on one surface of the substrate; and
an input unit configured to input a stimulus to which the stimulus-responsive gel reacts in a non-contact manner at an arbitrary position on the gel layer,
wherein adhesive regions where the substrate and the gel layer adhere to each other and a non-adhesive region where the substrate and the gel layer do not adhere to each other are formed at an interface between the substrate and the gel layer,
the adhesive regions are provided on both sides of the non-adhesive region in a plan view, and
the input unit inputs the stimulus to the gel layer overlapping the non-adhesive region.

2. The motion element according to claim 1, wherein the input unit inputs stimuli to a plurality of positions of the gel layer.

3. The motion element according to claim 1, wherein the input unit continuously moves a position where the stimulus is input to the gel layer.

4. The motion element according to claim 1, wherein the non-adhesive region is provided in a band shape on the one surface.

5. The motion element according to claim 4, wherein a plurality of the non-adhesive regions are provided.
